(19) United States
(12) Patent Application Publication
(10) Pub. No.: US 2007/0155180 A1
(43) Pub. Date: Jul. 5, 2007

(54) Thin film etching method

(75) Inventors: Chia-Che Hsu, Padeh City (TW); Yea-Chung Shih, Padeh City (TW); Mien-Jen Cheng, Padeh City (TW); Cheng-Chang Wu, Padeh City (TW); Jui-Chung Chang, Padeh City (TW)

Correspondence Address: Venable LLP;Raymond J. Ho, 575 7th Street NW, Washington, DC, 20004-1601, US

(73) Assignee: CHUNGHWA PICTURE TUBES, LTD., Padeh City (TW)

(21) Appl. No.: 11/325,323

(22) Filed: Jan. 5, 2006

(51) Int. Cl. H01L 21/311

(52) U.S. Cl. 438/703; 438/694

(57) ABSTRACT

A thin film etching method is provided, which is used for manufacturing semiconductor device or thin film transistor (TFT) array and through which no undercut may be presented or a good after-etching shape may be achieved with respect to a thin film thus etched. The thin film etching method is performed in a two-stage manner by an etchant and between the two stages a photoresist removing process is inserted where another etchant is used. With execution of the photoresist removing process, the thin film may have an increased contact area with the etchant. As such, any undercut or undesired after-etching shape existed in the thin film etched by the prior art may be eliminated or improved.

### BACKGROUND OF THE INVENTION

1. Field of the Invention

The present invention relates to a thin film etching method and particularly to a thin film etching method for manufacturing semiconductor device or thin film transistor (TFT) array to eliminate or improve an undercut or an undesired after-etching shape on the etched thin film.

2. Description of the Related Art

In manufacturing an electronic device or wires by using thin film technology, film forming, photoresistant coating, and film etching processes are generally involved based on the devised structure of the electronic device or wires. Among them, the etching process is used to remove a specific material by means of chemical reaction or physical striking so that the devised structure may be achieved. The etching process is roughly classified into a dry etching process and a wet etching process, the former being typically a plasma etching process while the latter being achieved by chemical reaction provided by chemical solutions.

With related to the wet etching process, a to-be-etched material may typically be found with a specific etchant through which the material may be efficiently and rapidly etched without etching other materials located adjacent to the material, i.e., the etchant is chosen so that it is equipped with a considerably high selectivity of the to-be-etched material with respect to the materials located adjacent thereto. Since chemical reaction does not have any inclination in direction, the wet etching process is in essence an isotropic etching process. The isotropic etching is thus termed since it may occur in a traverse direction and a longitudinal direction. The etching occurred in the traverse direction may cause an undercut. On the other hand, plasma used in the plasma etching process is partially de-ionized gas composed of positive charges (ions), negative charges (electrons) and neutral radicals. This etching process may advantageously present an anisotropic etching result. However, the dry etching process may not have a considerable selectivity as that of the wet etching process since ions striking may etch the thin film and the photoresist simultaneously.

FIG. 1A shows a schematic diagram of a gate of thin film transistor (TFT) liquid crystal display (LCD) after a photolithography process is executed. FIG 1B shows a schematic diagram of the gate of TFT shown in FIG. 1A when an etching process is applied. FIG. 1C shows a schematic diagram of the gate of LCD-TFT shown in FIG. 1B after a photoresist thereon is removed. In performing an array process with respect to a TFT-LCD, the gate is first formed by a physical vapor deposition (PVD) method, in which an aluminum-neodymium (AlNd) alloy is deposited on a substrate 10 as a first thin film 21 and then an aluminum-neodymium-nitrogen (AlNdN) is deposited thereon as a second thin film 22 so as to form a bi-layered metal structure. Next, the photolithography process is relied upon to define a pattern of the gate.

Then, by means of the photoresistant 30 the pattern is transferred onto the bi-layered metal structure thru a wet etching process. After a stripping process, the photoresistant is removed and the gate is completely formed by the array process. In this case, a poor taper is obtained with respect to the gate since the AlNdN alloy is etched more slowly as compared to the AlNd alloy in the bi-layered metal structure. Even, an undesired undercut may present in the gate.

FIGS. 2A, 2B, and 2C are schematic diagrams of a single-layered thin film structure with respect to an etching process, respectively. FIGS. 3A, 3B, and 3C are schematic diagrams of a tri-layered thin film structure with respect to an etching process, respectively. Specifically, FIGS. 2A and 3A are schematic diagrams of the thin film structures after a photolithography process is applied, respectively. FIGS. 2B and 3B are schematic diagrams of the thin film structures when the etching process is applied, respectively. FIGS. 2C and 3C are schematic diagrams of the thin film structures after a photoresistant thereon is removed, respectively. It may be known from the above drawings that not only the bi-layered metal structure may present the undercut or undesired after-etching shape when etched, but also the single or multiple structures may have an undesired etching result.

The disadvantages brought by the above undesired after-etching shape includes: 1. the thus formed undercut is a tapered conductor structure, tip discharging is easy to be generated and thus electrostatic charges may occur and cause the device to fail. 2. When the photoresist is removed, liquid or foreign matters are generally accumulated at the undercut. Thus, a passivation layer may not be properly formed on the undercut and the formed passivation layer is thus susceptible to float or coming off. 3. When the deficiencies mentioned in 1 and 2 are involved in scan line or data line structures, deficient circuit may occur in these structures.

### SUMMARY OF THE INVENTION

It is, therefore, an object of the present invention to eliminate or improve an undercut or an undesired after-etching shape on a thin film etched by a conventional etching method by modifying a manufacturing process for the thin film, in which an additional etching process is used to remove a photoresistant necessary for the thin film etching by increasing a contact area between the thin film and an etchant for the thin film.

To achieve the above object, a thin film etching method for manufacturing semiconductor device or TFT array is disclosed in the present invention, comprising the following steps: providing a substrate having at least a thin film formed thereon and further a photoresist on the thin film, etching the thin film by using a first etchant, etching the photoresist by using a second etchant and then re-etching the thin film by using the first etchant in the thin film etching step.

The thin film may be first etched by using a conventional etching method. When the thin film is etched to an extent where the thin film has a reduced contact area with the etchant due to the photoresist covering on the thin film, causing different etching rates with respect to different thin films, further causing an undercut or an undesired after-etching shape to present, the step of etching the photoresist is directed to be performed. By means of a proper etched amount, the photoresist area covering on the thin film may be reduced and thus deficient etching over the thin film may be improved. After the deficient etching source of the photoresist is removed, the thin film may be re-etched to obtain a good after-etching shape.

With execution of the present invention, at least the following advantages may be achieved. 1. The undercut may be eliminated or improved when the thin film is formed. 2. Deficient lines or dots may be prevented. 3. The thin film may be formed as required after-etching shape without presenting an acute angle or irregular shape. 4. With elimination of the undercut, tip discharging may be prevented from occurring and thus the device may not be caused to fail due to damage brought by the electrostatic charges. 5. With elimination of the undercut, liquid or foreign matters may not accumulate, a passivation layer may be better formed on the thin film and thus may not float or come off.

Further advantageous developments and convenient forms of the invention will be understood from the following detailed descriptive disclosure of embodiments thereof in conjunction with the accompanying drawings.

### BRIEF DESCRIPTION OF THE DRAWINGS

The accompanying drawings, which are incorporated into and constitute a part of this specification, illustrate embodiments of the present invention and, together with the detailed description, serve to explain the principles and implementations of the invention. The figures are not to scale. In the drawings:

FIG. 1A shows a schematic diagram of a conventional gate structure of TFT display after a photolithography process is executed;

FIG. 1B shows a schematic diagram of structure of the conventional gate structure of TFT shown in FIG. 1A when an etching process is applied;

FIG. 1C shows a schematic diagram of the conventional gate structure of TFT display shown in FIG. 1B after a photoresist thereon is removed;

FIG. 2A shows a schematic diagram of a conventional single-layered thin film structure after a photolithography process is performed;

FIG. 2B shows a schematic diagram of the conventional single-layered thin film structure shown in FIG. 2A when an etching process is applied;

FIG. 2C shows a schematic diagram of the conventional single-layered thin film structure shown in FIG. 2B after a photoresist is removed;

FIG. 3A shows a schematic diagram of a tri-layered thin film structure after a photolithography process is performed;

FIG. 3B shows a schematic diagram of the tri-layered thin film structure shown in FIG. 3A when an etching process is applied;

FIG. 3C shows a schematic diagram of the tri-layered thin film structure shown in FIG. 3B after a photoresist is removed;

FIG. 4 shows a flowchart of a thin film etching method according to the present invention;

FIG. 5A shows a schematic diagram of a bi-layered thin film structure after the photolithography process is performed according to the present invention;

FIG. 5B shows a schematic diagram of the bi-layered thin film structure shown in FIG. 5A after a first etching step is performed according to the present invention;

FIG. 5C shows a schematic diagram of the bi-layered thin film structure shown in FIG. 5B after a second etching process is performed according to the present invention;

FIG. 5D shows a schematic diagram of the bi-layered thin film structure shown in FIG. 5C when a third etching step is performed according to the present invention;

FIG. 5E shows a schematic diagram of the bi-layered thin film structure as shown in FIG. 5D after the third etching process;

FIG. 5F shows a schematic diagram of the bi-layered thin film structure shown in FIG. 5E after the photoresist is removed according to the present invention;

FIG. 6A shows a schematic diagram of a single-layered thin film structure after the photolithography process is performed according to the present invention;

FIG. 6B shows a schematic diagram of the single-layered thin film structure shown in FIG. 6A when a first etching step is performed according to the present invention;

FIG. 6C shows a schematic diagram of the single-layered thin film structure shown in FIG. 6B when a second etching step is performed according to the present invention;

FIG. 6D shows a schematic diagram of the single-layered thin film structure shown in FIG. 6C when a third etching step is performed according to the present invention;

FIG. 6E shows a schematic diagram of the bi-layered thin film structure as shown in FIG. 6D after the photoresist is removed according to the present invention;

FIG. 7A shows a schematic diagram of a tri-layered thin film structure after the photolithography process is performed according to the present invention;

FIG. 7B shows a schematic diagram of the tri-layered thin film structure shown in FIG. 7A when a first etching step is performed according to the present invention;

FIG. 7C shows a schematic diagram of the tri-layered thin film structure shown in FIG. 7B when a second etching step is performed according to the present invention;

FIG. 7D shows a schematic diagram of the tri-layered thin film structure shown in FIG. 7C when a third etching step is performed according to the present invention; and

FIG. 7E shows a schematic diagram of the tri-layered thin film structure as shown in FIG. 7D after the photoresist is removed according to the present invention.

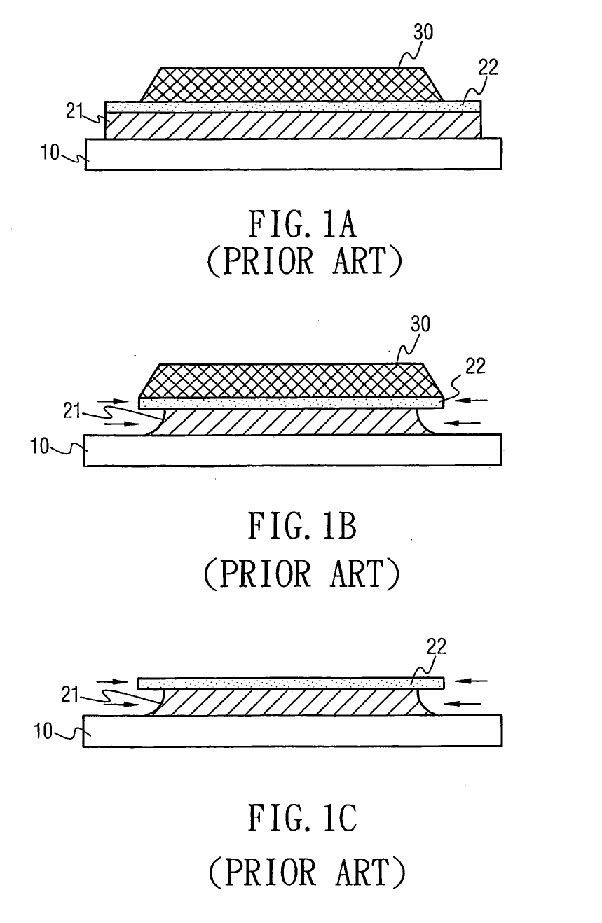

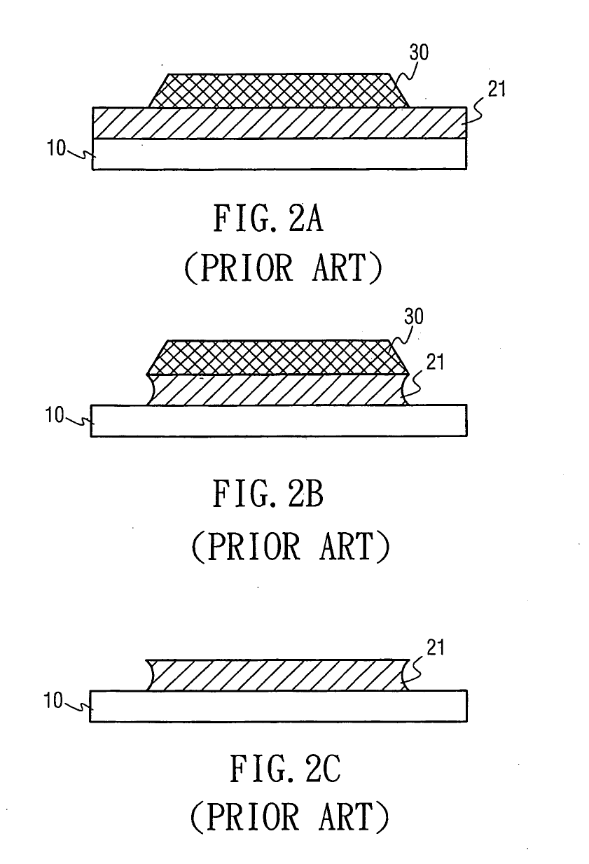

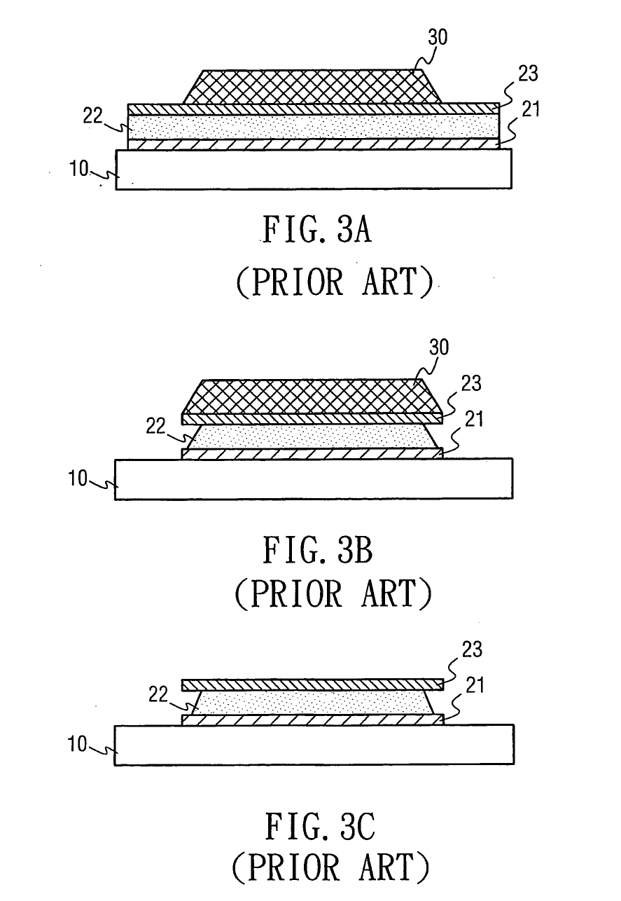

### DETAILED DESCRIPTION OF THE INVENTION

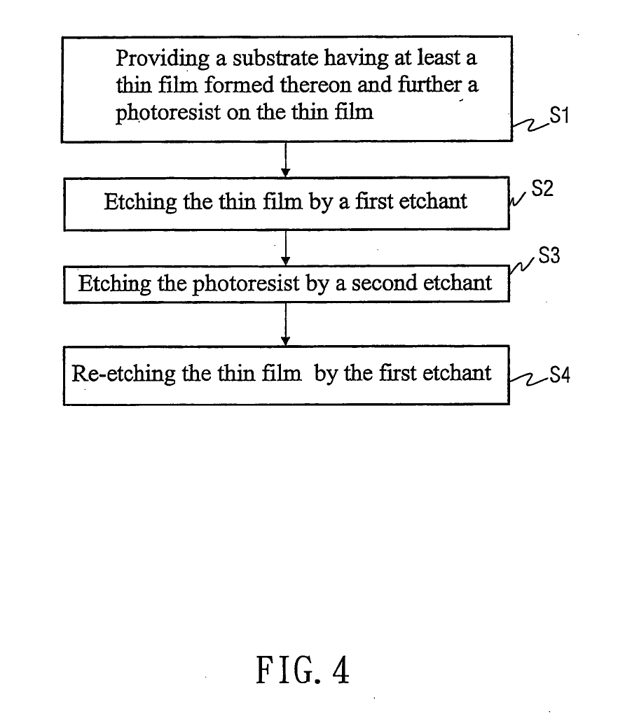

FIG. 4 shows a flowchart of a thin film etching method according to the present invention. The thin film etching method is generally for manufacturing semiconductor device or TFT array. As shown, the thin film etching method comprises the following steps. First, a substrate is provided, having at least a thin film formed thereon and a photoresist formed on the thin film (S1). Next, a first etching step is performed on the thin film by a first etchant (S2) and then a second etching step is performed on the photoresist by a second etchant (S3). Finally, a third etching step is performed on the thin film to etch again the thin film by the first etchant (S4).

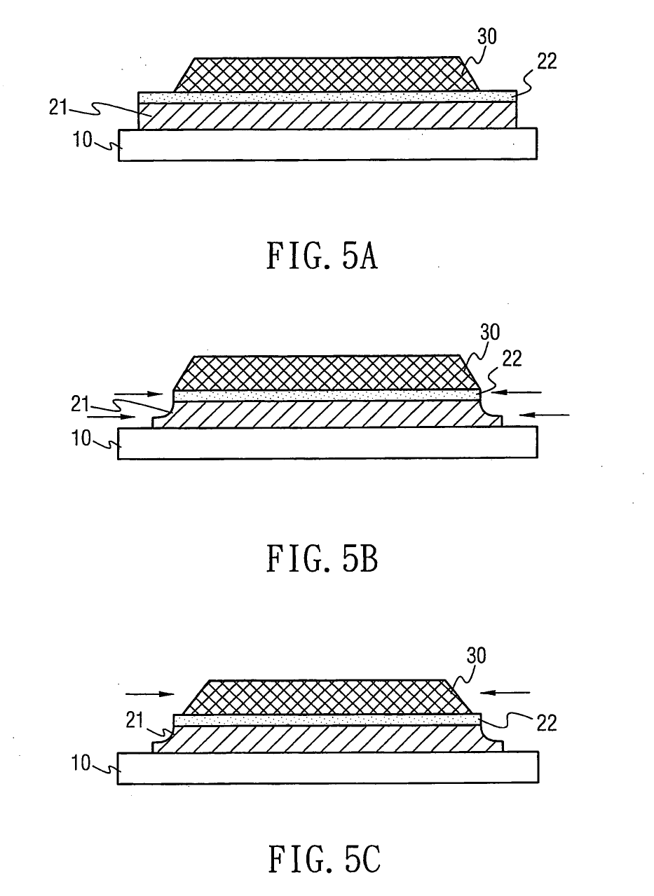

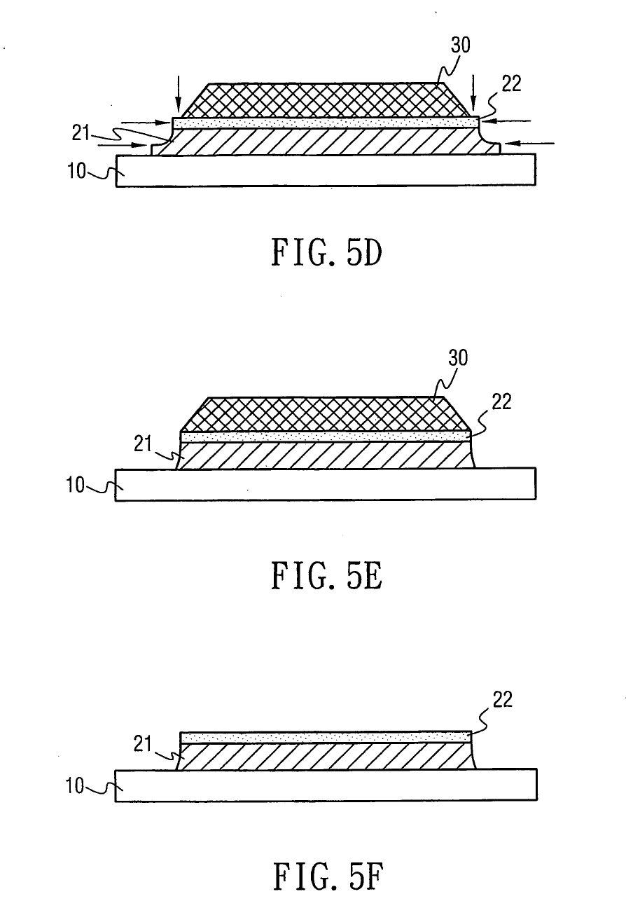

FIG. 5A shows a schematic diagram of a bi-layered thin film structure after the photolithography process is performed according to the present invention. FIG. 5B shows a schematic diagram of the bi-layered thin film structure shown in FIG. 5A after a first etching step is performed according to the present invention. FIG. 5C shows a schematic diagram of the bi-layered thin film structure shown in FIG. 5B after a second etching process is performed according to the present invention. FIG. 5D shows a schematic diagram of the bi-layered thin film structure shown in FIG. 5C when a third etching step is performed according to the present invention. FIG. 5E shows a schematic diagram of the bi-layered thin film structure as shown in FIG. 5D after the third etching process. FIG. 5F shows a schematic diagram of the bi-layered thin film structure shown in FIG. 5E after the photoresist is removed according to the present invention.

This embodiment will be described with respect to an array process for TFT-LCD, which is taken as an example herein for illustration only.

When a gate of the array is to be manufactured, a substrate 10 is first provided. On the substrate 10, an AlNd alloy and an AlNdN alloy are formed as a first thin film 21 and a second thin film 22, respectively, which jointly forms a bi-layered thin metal film. On the second thin film 22, a photoresist 30 is further formed.

In performing the first etching step, the conventional wet etching process is used to etch the first and second thin films 21, 22. Since the wet etching process features an isotropic etching result, traverse and longitudinal etching results may occur simultaneously with respect to the bi-layered thin metal film structure. In this case, the first thin film 21 is etched at a rate of 2100 Å/min. while the second thin film 22 etched at a rate of 300 Å/min. After an etching time, the different etching rates can result in an undercut on the structure due to the traverse etching effect.

Since the second thin film still has a large portion to be etched with respect to the final pattern thereof, the etching manner may be modified to prevent the undercut or the undesired after-etching shape from presenting. Specifically, with provision of the photoresist 30, the first thin film 21 is contacted with the etchant at a reduced portion thereof, causing inconsistent etching rates with respect to the first and second thin films 21, 22. When the undercut or undesired after-etching shape presents, the second etching step is directed to be performed.

The second etching process is performed on the photoresist 30 after the first etching process. Generally, when an undercut is presented during the first etching process performed or almost presented, the second etching process is launched. In performing the second etching process, a dry etching method is used, particularly an oxygen containing plasma etching (O2 Plasma) method. The feature of anisotropic etching inherent in the dry etching method is used to remove a portion of the photoresist 30 so that the second thin film 22 is less covered by the photoresist 30 in area and thus has a bigger portion in chemical reaction with the etchant. In conclusion, the second etching process is primarily used to prevent the photoresist 30 from covering the undercut formed by the first etching process.

The third etching process is performed on the thin film after the second etching process is performed so that the thin film is again etched. This etching process is similar to the first etching process in etching mechanism. After the second etching process is performed, the second thin film 22 is less covered by the photoresist 30 in area as above mentioned and thus the second thin film 22 has a bigger portion in chemical reaction with the etchant used in the third etching process. Further, the first and second thin metal films have a same chemical reaction rate, about 2100 Å/min, so that the undercut formed owing to the different chemical reaction rates may be improved.

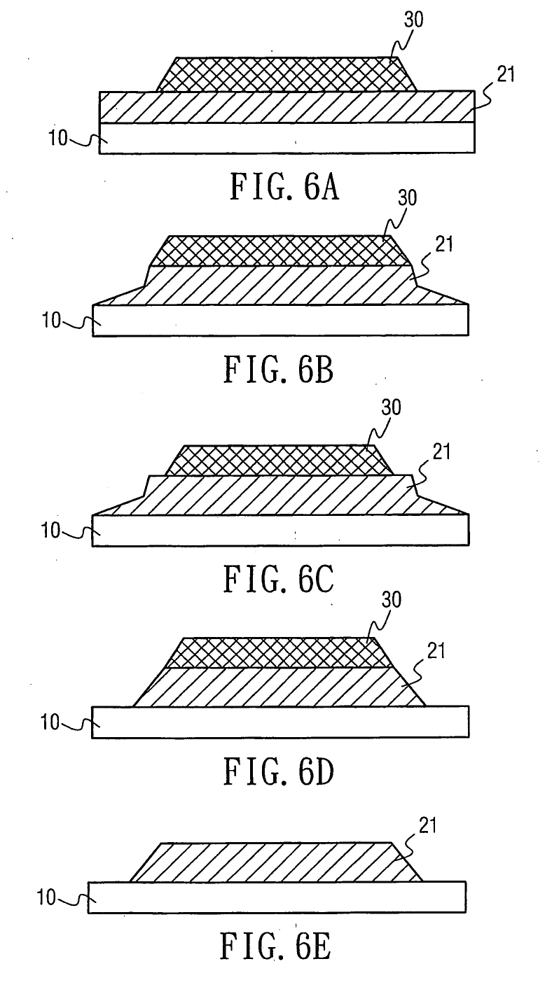

FIG. 6A shows a schematic diagram of a single-layered thin film structure after the photolithography process is performed according to the present invention. FIG. 6B shows a schematic diagram of the single-layered thin film structure shown in FIG. 6A when a first etching step is performed according to the present invention. FIG. 6C shows a schematic diagram of the single-layered thin film structure shown in FIG. 6B when a second etching step is performed according to the present invention. FIG. 6D shows a schematic diagram of the single-layered thin film structure shown in FIG. 6C when a third etching step is performed according to the present invention. FIG. 6E shows a schematic diagram of the single-layered thin film structure as shown in FIG. 6D after the photoresist is removed.

This embodiment is adapted to etching of a single-layered thin film structure. First, a substrate 10 is provided and then a first thin film 21 is formed on the substrate 10. The first thin film 21 is a chromium (Cr) film or a molybdenum (Mo) film. Further, a photoresist 30 is formed on the first thin film 21. Then, the first, second and third etching processes are performed in sequence, in which the first and third etching processes are performed on the first thin film 21 while the second etching process is performed on the photoresist 30, as is the same as that described for the bi-layered thin film structure and the related description is omitted here for simplicity. Similarly, the undercut produced in this embodiment may be eliminated and thus the after-etching shape of the first thin film 21 may become better.

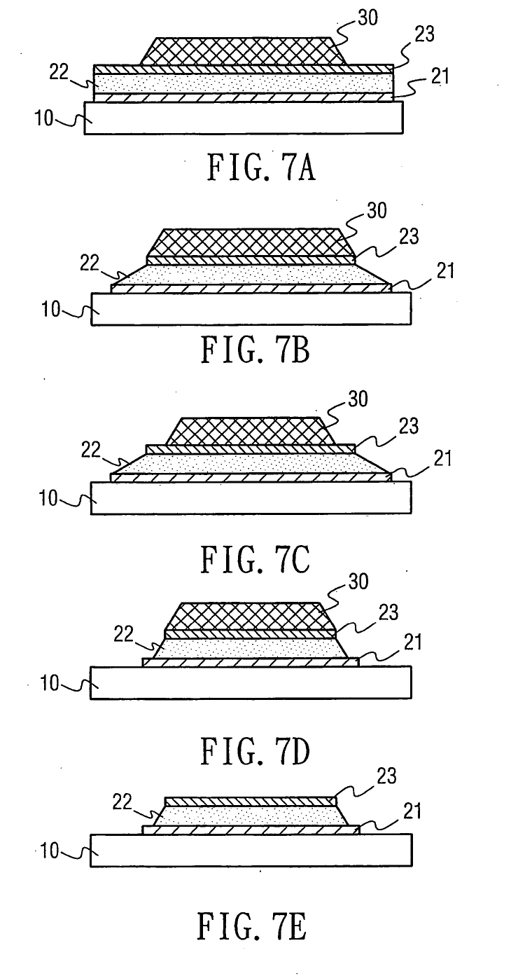

FIG. 7A shows a schematic diagram of a tri-layered thin film structure after the photolithography process is performed according to the present invention. FIG. 7B shows a schematic diagram of the tri-layered thin film structure shown in FIG. 7A when a first etching step is performed according to the present invention. FIG. 7C shows a schematic diagram of the tri-layered thin film structure shown in FIG. 7B when a second etching step is performed according to the present invention. FIG. 7D shows a schematic diagram of the tri-layered thin film structure shown in FIG. 7C when a third etching step is performed according to the present invention. FIG. 7E shows a schematic diagram of the tri-layered thin film structure as shown in FIG. 7D after the photoresist is removed according to the present invention.

This embodiment is adapted to etching of a tri-layered or multiple thin film structure. First, a substrate 10 is provided and then a Mo layer, an aluminum (Al) layer and a Mo layer are formed as a first, a second, and a third thin films 21, 22, 23, respectively, on the substrate 10. Further, a photoresist 30 is formed on the third thin film 23. Alternatively, the first, second and third thin films 21, 22, 23 may be made of Cr, Al, Cr, or other materials, respectively.

Then, the first, second, and third etching processes are performed in sequence, in which the first and third etching processes are performed on the first, second and third thin films 21, 22, 23 while the second etching process is performed on the photoresist 30, as is the same as that described for the bi-layered thin film structure and the related description is omitted here for simplicity. Similarly, the undercut produced in this embodiment may be eliminated and thus the etched shape of the first thin film may become better.

The ingredients of the first etchant and the second etchant used in the embodiment of present invention may be a mixed solution of phosphoric acid, nitric acid, and acetic acid if the material of the first film 21 and the second film 22 is aluminum or aluminum alloy.

Although the present invention has been described in terms of specific embodiment, it is anticipated that alterations and modifications thereof will no doubt become apparent to those more skilled in the art. It is therefore intended that the following claims be interpreted as covering all such alterations and modification as fall within the true spirit and scope of the invention.

What is claimed is:

1. A thin film etching method for manufacturing semiconductor device or thin film transistor (TFT) array, comprising the following steps:
providing a substrate having at least one thin film formed thereon and further forming a photoresist on said thin film;
etching said thin film by a first etchant;
etching said photoresist by a second etchant; and
re-etching said thin film by said first etchant.

2. The thin film etching method according to claim 1, wherein said step of said thin film is a wet etching method.

3. The thin film etching method according to claim 1, wherein said step of etching said photoresist is achieved by using a dry etching method including an oxygen-containing plasma etching (O2 Plasma) method.

4. The thin film etching method according to claim 1, wherein said step of re-etching said thin film is achieved by a wet etching method.

5. The thin film etching method according to claim 1, wherein said thin film is a single-layered thin film structure.

6. The thin film etching method according to claim 1, wherein said thin film is a multi-layered thin film structure.

7. The thin film etching method according to claim 1, wherein said step of etching said photoresist is performed so that said photoresist does not cover an undercut produced in said step of etching said photoresist.

8. The thin film etching method according to claim 1, wherein said thin film is a thin metal film structure.

9. The thin film etching method according to claim 1, wherein said first etchant is a mixed solution of phosphoric acid, nitric acid, and acetic acid.

10. The thin film etching method according to claim 1, wherein said second etchant is a mixed solution of phosphoric acid, nitric acid, and acetic acid.

11. The thin film etching method according to claim 1, wherein said thin film on said substrate is a bi-layered thin film structure.

12. The thin film etching method according to claim 11, wherein said bi-layered thin film structure comprises a first thin film made of an aluminum-neodymium (AlNd) alloy.

13. The thin film etching method according to claim 11, wherein said bi-layered thin film structure comprises a second thin film made of an aluminum-neodymium-nitrogen (AlNdN) alloy.

14. The thin film etching method according to claim 1, wherein said thin film on said substrate is a tri-layered thin film structure.

15. The thin film etching method according to claim 14, wherein said tri-layered thin film structure comprises a first thin film made of molybdenum (Mo).

16. The thin film etching method according to claim 14, wherein said tri-layered thin film structure comprises a second thin film made of aluminum (Al).

17. The thin film etching method according to claim 14, wherein said tri-layered thin film structure comprises a third thin film made of molybdenum (Mo).
